(19) United States
(12) Patent Application Publication
(10) Pub. No.: US 2004/0047121 A1
(43) Pub. Date: Mar. 11, 2004

(54) Apparatus for EMI/RFI hardening of off-the-shelf computers

(76) Inventor: John Hope, Eliot, ME (US)

Correspondence Address: LEONARD TACHNER, A PROFESSIONAL LAW, CORPORATION, 17961 SKY PARK CIRCLE, SUITE 38-E, IRVINE, CA, 92614

(21) Appl. No.: 10/659,636

(22) Filed: Sep. 8, 2003

Related U.S. Application Data
(60) Provisional application No. 60/409,817, filed on Sep. 10, 2002.

(51) Int. Cl. H05K 5/00

(52) U.S. Cl. 361/683

(57) ABSTRACT

An apparatus for hardening a computer against potential extortion or remote reading of data. It consists of an enclosure that can be adapted to fit any commercially available off-the-shelf computer product (Servers and Personal Computer Towers), and a set of filters & shielding to transfer the energy from the power cord and other peripherals to the computer. All of the energy, EMI, RFI, and magnetic fields within the computer are kept there. Any potential energy, EMI, RFI, or HERF blasts from outside the computer are kept there. The invention allows an existing computer product to be mounted inside the enclosure, adequately supported and shielded to meet all hardening requirements to prevent magnetic or electronic energy from entering or leaving the computer.

### CROSS-REFERENCE TO RELATED APPLICATIONS

This application takes priority from Provisional Application Serial No. 60/409,817 filed on Sep. 10, 2002.

### BACKGROUND OF THE INVENTION

1. Field of the Invention

The present invention relates generally to protection of computer data from external sensors of VLF propagations and more specifically to an enclosure which prevents such propagation.

2. Background Art

Reports on the electronics computing industry describe security breaches by systems that can monitor normal computer terminals from considerable distances away. These systems can read keystrokes as data is entered into the computer, reconstruct the images displayed on the monitor or CRT, and can ‘read’ data is that is being transmitted internally within the system.

The physics of such systems depends upon Very Low Frequency (VLF) radio propagation. When a byte of data is transmitted in a computer across any conductive path, whether it be to from the key board to the CPU; from the CPU to memory; or from the CPU to the monitor, this flow of current creates a magnetic field. The shape and orientation of that magnetic field is different for each character, which could distinguish it and allow it to be precisely measured from a remote location.

The magnetic field and the associated electrical field create a radio wave that propagates out from the CPU at the speed of light. At normal communications frequencies, shielding could stop these radiations by surrounding the room, the computer, or the electronic device with a metal screen that reflects the energy to keep it inside the room or electronic device. Microwave ovens use such screening to keep the energy inside. However, the fields created by computers and peripherals are very low frequencies and do not propagate as normal radio frequencies. These frequencies have a very long wavelength and are called “evanescent” or near-field waves. Such waves fall off in intensity, dropping to approximately one third their original value in a single wavelength. One wavelength, in this case, is one or more kilometers. These fields also couple energy to other conductors or current conducting cables nearby, such as the power cord of the computer. This power cord helps couple the energy into the power lines coming into the room and they, in turn, form a much bigger magnetic antenna that couples to the building and into the power grid and into the surrounding neighborhood.

At any distance, the actual pattern seen by a loop antenna connected to the power grid or picking up the signals via airwaves is completely unpredictable. There is no practical way to predict what the “signature” of any specific character would be. It will vary from one computer to another and from one location to another. However, by using time correlation of signals picked up in different locations around the building, the signals from certain offices can be made stronger than from others. This is a technique used to improve sonar monitoring in the oceans. In addition, techniques developed by the British in World War II and described in the “Enigma” stories can be used to interpret the sequences of letters. The signals are typed in Standard English and common words, phrases, and symbols can be used to decode the sentence. With today's computer speed and memory, correlation techniques can be used in real time to detect the computer input.

Further reports on the electronics computing industry describe terrorists and/or extortionists armed with High Energy Radio Frequency (or HERF) devices who have been known to threaten or even attack the electronics infrastructure of businesses, governments, and military devices. In essence, HERF devices are nothing but special-purpose radio transmitters. HERF devices are able to release a high-power radio signal at an electronic target and put it out of function. The damage can be moderate or severe, depending on the amount of power used. Moderate damage is when a system shuts down but can be restarted. Severe damage is when the system hardware has been physically damaged and must be replaced. Electronic circuits are quite vulnerable to overload in this manner.

To date, all attempts to prevent these monitoring techniques or extortion techniques have utilized highly customized computers and highly customized techniques of shielding the CPU's, the input/output devices, and the power cables. This required the users to purchase custom built computers, rather than being able to take advantage of the high quality commercial-off-the-shelf name-brand computer products. Many times the user has a familiarity with the commercial product, the world-wide organization established for service of the product, the software compatibility, and user friendliness that they employ. But the custom built computers are most frequently totally custom designed, custom built devices that do not have the service organizations or proven software & applications compatibility that the user would prefer. Another disadvantage of these products is that they have very limited availability of options and are typically much older technology. Many times these computers use microprocessors or memory speeds that are three or more product revisions outdated (in computer products, being more than one revision out-of-date often means that key software applications will not operate effectively or efficiently).

Therefore, the user has had to chose between a commercially available off-the-shelf product with virtually unlimited options, state-of-the art designs, user friendly/ergonomic design, latest revisions of hardware and software, world wide service organizations, and affordable pricing in a product that is not “hardened”, or a highly custom, limited options, one design fits all, limited service, outdated process & memory designs product that is “hardened”.

Based upon the known phenomenon of electromagnetic emissions and transient voltage surges a variety of filter and suppression circuit configurations have been designed as is evident from the prior art. A detailed description of the various inventions in the prior art is disclosed in U.S. Pat. No. 5,142,430, herein incorporated by reference.

The present invention is a new technique for hardening a computer against potential extortion or remote reading of data. It consists of an enclosure that can be adapted to fit any commercially available off-the-shelf computer product (Servers and Personal Computer Towers), and a set of filters & shielding to get the energy from the power cord and other peripherals to the computer. All of the energy, EMI, RFI, and magnetic fields within the computer are kept inside. Any potential energy, EMI, RFI, or HERF blasts from outside the computer are kept outside. The invention allows an existing computer product to be mounted inside the enclosure, adequately supported and shielded to meet all hardening requirements to prevent magnetic or electronic energy from entering or leaving the computer.

### SUMMARY OF THE INVENTION

The invention comprises an apparatus for hardening a computer against damage by high energy radio frequency devices or remote reading of data. It consists of an enclosure that can be adapted to fit any commercially available off-the-shelf computer product (Servers and Personal Computer Towers), and a set of filters & shielding to get the energy from the power cord and other peripherals to the computer. All of the energy, EMI, RFI, and magnetic fields within the computer are kept in the computer. Any potential energy, EMI, RFI, or HERF blasts from outside the computer are kept outside. The invention allows an existing computer product to be mounted inside the enclosure, adequately supported and shielded to meet all hardening requirements to prevent magnetic or electronic energy from entering or leaving the computer.

The present invention solves the problem of preventing unwanted electronic energy into the computer and preventing signals from escaping the computer. It incorporates that same technique in an off-the-shelf enclosure that can be installed on any existing computer to make it conform to the same standards of performance.

In this invention the existing computer is fitted with mounting & supporting brackets on the bottom of the tower and the top of the tower. The enclosure has been certified to conform to all “hardened” requirements and therefore any product, which has been properly installed within it, will also conform to those same requirements. The computer tower, fitted with the above mentioned brackets, is slid into the enclosure and the brackets are screwed to the supporting members in the top and the bottom of the enclosure.

The front of the enclosure contains an access door with cipher lock. This prevents unauthorized access to the unit and its hard drives.

All of the removable panels on the enclosure, (front door, rear panel, and 2 side panels) are sealed using overlapping metal techniques with numerous screws. These seals are further protected through the use of EMI/RFI shielding gaskets. These EMI/RFI shielding gaskets maintain shielding effectiveness across any seam or gap in the overlapping metal structure of the enclosure. They consist of metallized fabric wrapped around a neoprene elastomer core.

The rear of the computer product is fitted with shielded cable assemblies for all peripherals and a shielded & filtered cable assembly for the power cord. This prevents attachment of unprotected and/or unqualified products to the unit and provides the protection for the signals as they leave the computer product. These cable assemblies terminate into specialty connectors that are mounted to the rear door of the enclosure.

The theory or the effectiveness of these filtered connector assemblies may be described by insertion loss. Insertion loss (Lᵢ) is a measurement of the effectiveness of a filter. Lᵢ is defined as the ratio of the voltage (V₁) across the circuit load without the filter to the voltage (V₂) across the load with the filter. Since the insertion loss is dependent upon the source and the load impedance in which the filter is to be used, Lᵢ measurements are defined for a matched 50 ohm system. The insertion loss is measured in decibels (dB) and defined as follows:

Lᵢ (dB)=20 log [V₁/V_{2]}

In practical circuit applications, the source and load impedances may be very different from 50 ohms. If these impedances are known, the anticipated insertion loss may be estimated by the following equation:

Lᵢ (dB)=20 log [1+(ZₛZ_{L})/(Zₜ(Zₛ+Z_{L}))]

Where:

Zₛ=Source impedance in ohms

Z_{L}=Load impedance in ohms

Zₜ=Transfer impedance in a 50 ohm system

The fans in the original computer product are the only air flow needed, as they are not blocked off, but are filtered through specialty filters to prevent any magnetic fields from entering or exiting via those openings. The theory of these air flow filters is a proven technology in the science of preventing electronic or magnetic pulses from entering or leaving areas being protected. Electronic or magnetic pulses travel via cyclical wave patterns much like the waves in a body of water. When they strike a surface, there will be some resonance, or bouncing of the energy wave. The filtering method of attenuating electromagnetic radiation consists of subjecting the radiation to a plurality of resonant cavities having different resonant frequencies and modifying the cavities so that the radiation within a specific cavity is blocked by adjacent cavities. This is accomplished by using multiple layers of conducting and non-conducting materials, which are overall porous to allow air flow, but do not allow magnetic charges to flow. The electromagnetic radiation first strikes an electrically conductive planar surface, resulting in a first portion of the electromagnetic radiation not passing through the substance and a second portion of the electromagnetic radiation (2^{nd} & 3^{rd} harmonic frequencies) passing through the first level. By calculating the remaining frequencies that pass through the surface and subjecting the passed radiation to additional electrically conductive surfaces, the additional surfaces are removably mounted in relationship to the first electrically conductive substrate to attenuate the passed electromagnetic radiation having the determined frequencies. This is accomplished by having the additional electrically conductive planar surfaces juxtaposed along a line perpendicular to the plane of the first surface and in a direction opposite from the point of origin of the electromagnetic radiation. Typical examples of screens or windows designed into EMI attenuation devices are disclosed in U.S. Pat. Nos. 4,701,801; 5,012,041; 5,017,419; 5,239,125; and 5,295,046. When screens are utilized, one determinant of the shielding effectiveness is a function of the distance between the grid wires of each individual screen.

The CRT or Computer Monitor to be used is an LCD device, which by definition does not emit any magnetic fields, EMI, or RFI signals that may be detected remotely. A photonic keyboard is used to prevent any remote detection of signals from the keyboard.

Thus this invention makes it possible to utilize commercial-off-the-shelf computer tower products in a hardened application.

### BRIEF DESCRIPTION OF THE DRAWINGS

The aforementioned objects and advantages of the present invention, as well as additional objects and advantages thereof, will be more fully understood hereinafter as a result of a detailed description of a preferred embodiment when taken in conjunction with the following drawings in which:

FIG. 1a depicts the front panel of a preferred embodiment with cipher lock for limited access;

FIG. 1b is a the side view showing a computer installed within the enclosure;

FIG. 1c is a the rear view of the enclosure showing the input/output ports and the power ports;

FIG. 2 and FIG. 3 are views of gaskets used on removable panels front, rear, and sides;

FIG. 4 is a plan view of an air filter assembly of the invention;

FIG. 5, comprising FIGS. 5a and 5b, is a view of the filtered cable assembly used for a 15 pin D-Sub connector;

FIG. 6, comprising FIGS. 6a and 6b, is a view of the filtered cable assembly used for a 25 pin D-Sub connector;

FIG. 7, comprising FIGS. 7a, 7b and 7c, is a view of the filtered gasket used for an AC power inlet assembly;

FIG. 8, comprising FIGS. 8a and 8b, is a view of the filtered gasketing used for removable panels;

FIG. 9, comprising FIGS. 9a and 9b, is a view of the filtered cable assembly used for a Mini-DIN connector;

FIG. 10, comprising FIGS. 10a and 10b, is a view of the filtered cable assembly used for a RJ-45 connector;

FIG. 11, comprising FIGS. 11a, 11b and 11c, is a view of the filtered gasket used for mounting of I/O connectors.

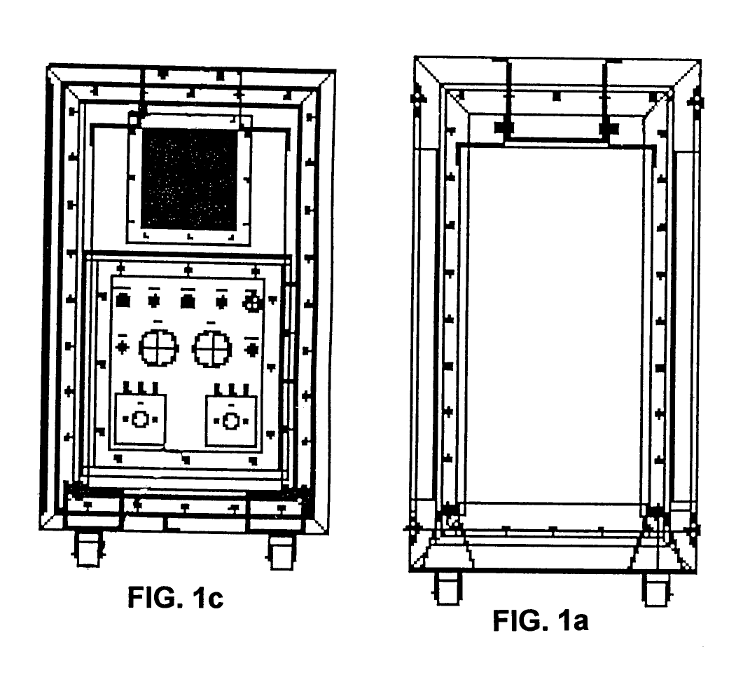

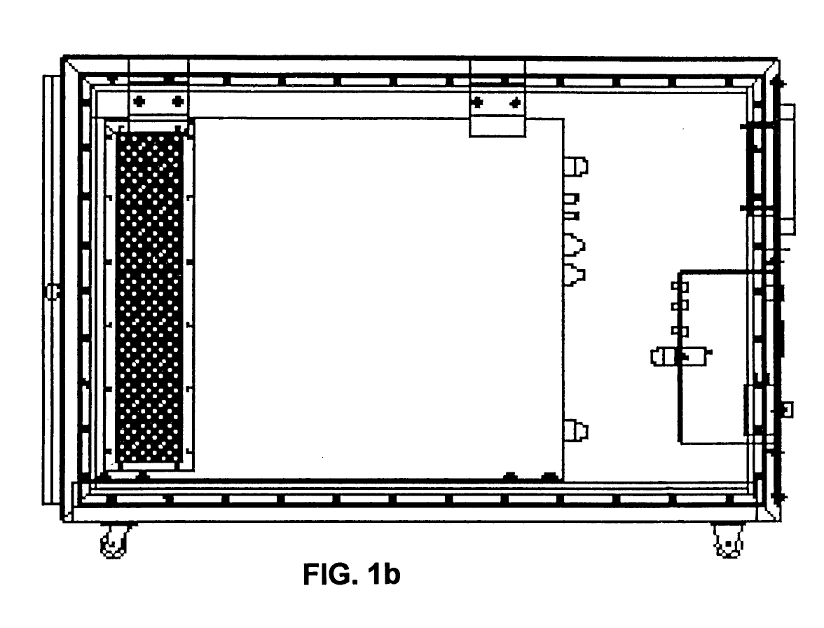

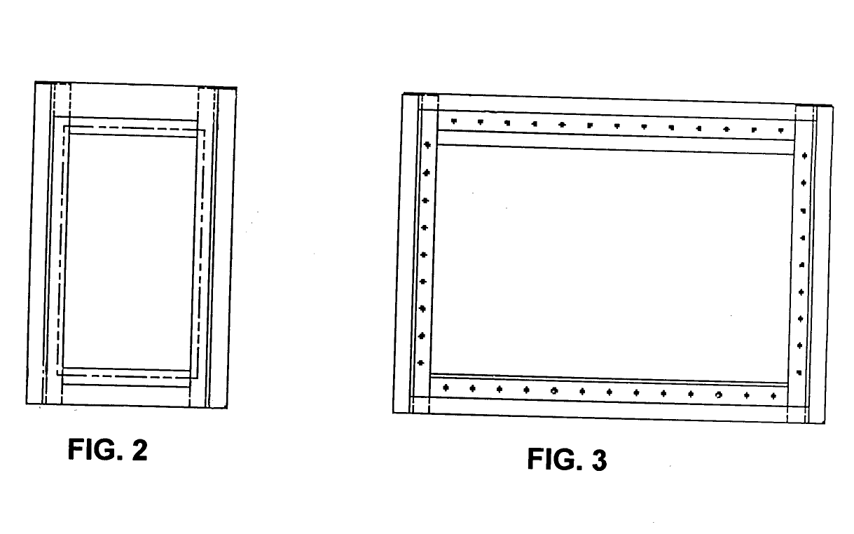

### DETAILED DESCRIPTION OF A PREFERRED EMBODIMENT

As shown in the accompanying figures, the enclosure can accommodate any commercially available tower style computer station. With adjustments only in the top and bottom mounting brackets (see FIG, 1) different dimensions may be accommodated without compromising the integrity of the computer hardening against transmitting or receiving any electronic or magnetic pulses.

Brackets on the top and bottom of the server allow it to be firmly mounted into the enclosure, without having to drill or make a permanent attachment to the server chassis. These connections are adjustable for different makes and models of computer products and are easily scaleable.

The enclosure incorporates a unique concept of allowing the user to use any commercial computer product and make that product meet the computer hardening requirements to prevent any transmitting or receiving of electronic or magnetic pulses.

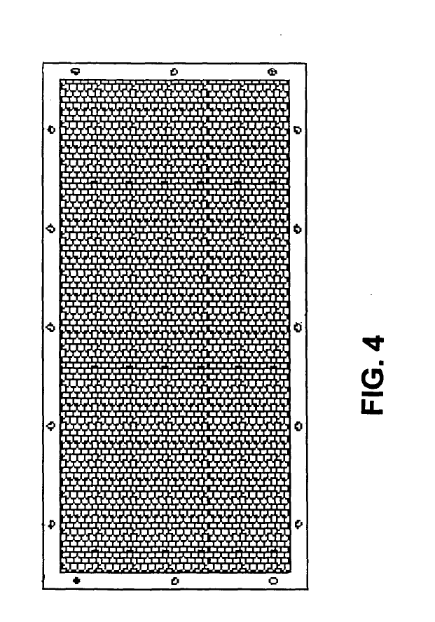

This is accomplished by use of air filters (see FIG. 4) that allow flow of cooling air (necessary for the continued operation of the computer) while preventing the intake or exhaust to contain any measurable EMI, RFI, or other magnetic fields that could potentially contain data information or harmful charges.

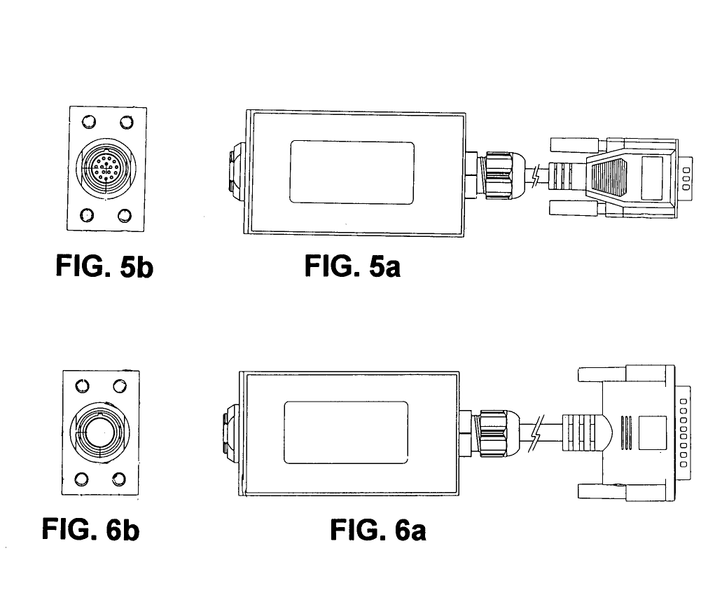

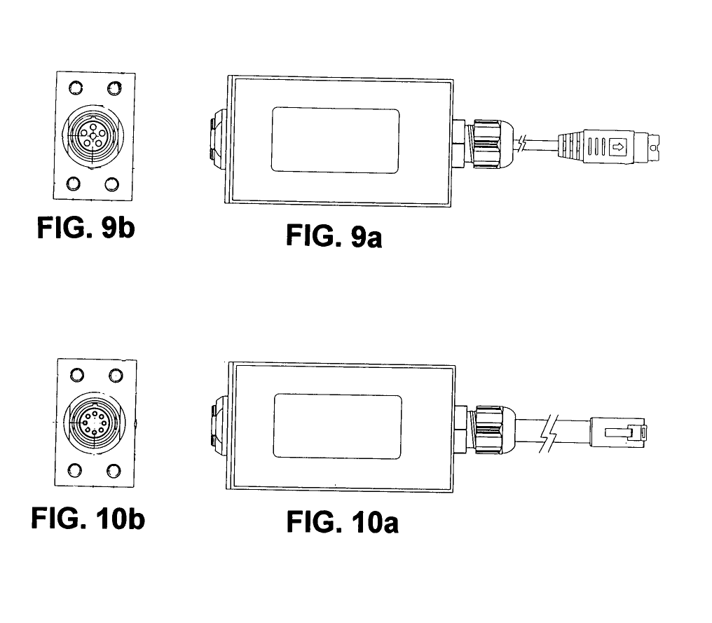

The input and output devices are connected to the computer by means of filtering circuits within the enclosure. A standard connector is attached to a short length of cable that leads to the filter circuit for that cable. Coming out of the filtering circuit is a ruggedized connector that exits the rear panel of the enclosure (see FIGS. 5, 6, 9 and 10). This is a dual feature connector. The connector is not a commercial connector, thus eliminating the potential for the user to plug a non-EMI/RFI/Magnetic pulse hardened device to the computer within the enclosure by accident. This insures the integrity of the overall system. These connectors can withstand high impact without sustaining damage. This will prevent wear and tear on the cables and/or connectors from allowing data leakage. It is very common among computer users to damage connectors and/or cables.

The preferred embodiment is also very rugged. It is constructed of heavy gauge steel and the overall unit without an installed computer weighs approximately 100 pounds. This embodiment will withstand normal impact without developing potential breaches in the shielding and/or gasketing that could let EMI, RFI, or magnetic fields enter or escape.

The seams on the sides, the rear, and the front feature a double protection mechanism which includes both overlapping steel flanges with large numbers of fastening screws and EMI/RFI gaskets to further prevent emissions (see FIG. 8).

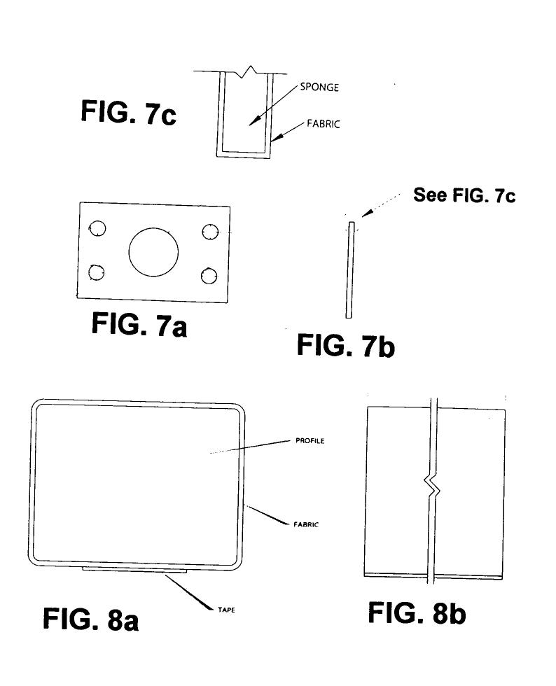

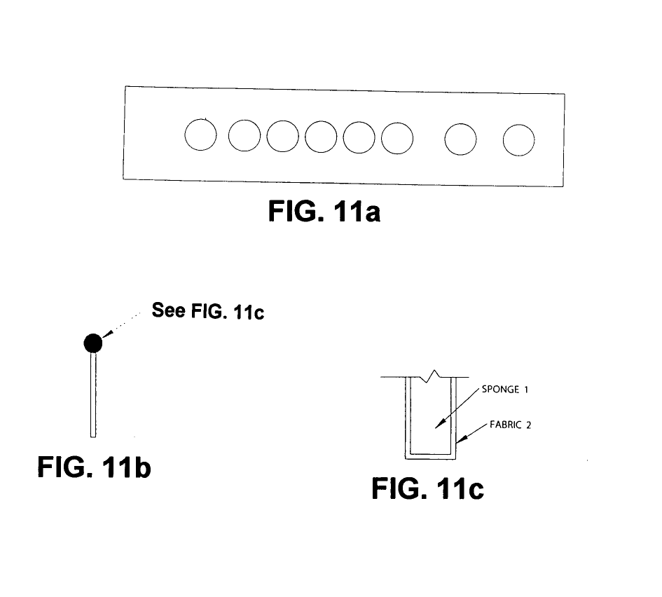

The computer sits several inches from the back panel. Filtered cable assemblies are attached from the back of the computer to the back panel. This prevents EMI/RFI from entering or exiting via the input/output cables and/or connectors (see FIGS. 7 and 11).

Having thus disclosed a preferred embodiment of the invention, it will be understood that other embodiments are contemplated as well as modifications to the illustrated version. Accordingly, the scope hereof is not limited to the disclosed details, but only to the underlying inventive features.

1. An apparatus for electromagnetically isolating a computer from the surrounding environment for preventing a transfer of electrical and magnetic field energy between the computer and the environment; the apparatus comprising:
an enclosure having a plurality of metal panels having overlapping edges fastened to one another and forming an internal chamber configured for receiving a computer;
a plurality of shielding gaskets positioned along said overlapping edges across all seams and gaps between said panels; and
at least one of said panels having a plurality of ruggedized connectors for electrical connection of cables to external peripheral computer devices and for electrical connection within said enclosure to said computer.

2. The apparatus recited in claim 1 further comprising a plurality of filtered cable assemblies within said enclosure for connecting said ruggedized connectors to said computer.

3. The apparatus recited in claim 1 further comprising a plurality of brackets affixed in said internal chamber for securing said computer within said enclosure.

4. The apparatus recited in claim 3 wherein said brackets are positioned for locating said computer at a selected distance from said ruggedized connectors.

5. The apparatus recited in claim 1 wherein at least one of said panels comprises an integral air filter for allowing air flow between said internal chamber and said environment.

6. The apparatus recited in claim 1 wherein said panels are made of heavy gauge steel.

7. A computer enclosure configured for accommodating any one of a plurality of commercially available computer towers, the enclosure being used for preventing unauthorized monitoring of signals emanating from an enclosed computer tower, the enclosure comprising:
a metal housing forming an internal chamber, at least one surface of said housing having a plurality of panel-mounted connectors for attaching cables to exterior computer peripheral devices; and
a plurality of filtered cable assemblies within said internal chamber for connecting said panel-mounted connectors to a computer within said chamber.

8. The apparatus recited in claim 7 further comprising a plurality of brackets affixed in said internal chamber for securing said computer within said enclosure.

9. The apparatus recited in claim 8 wherein said brackets are positioned for locating said computer at a selected distance from said ruggedized connectors.

10. The computer enclosure recited in claim 7, said metal housing comprising at least one integral air filter for allowing air flow through said housing.

11. The computer enclosure recited in claim 7 wherein said metal housing comprises a plurality of metal panels having overlapping edges fastened to one another.

12. The computer enclosure recited in claim 11 further comprising a plurality of shielding gaskets positioned along said overlapping edges across all seams and gaps between said panels.

13. The computer enclosure recited in claim 7 further comprising a power supply filter for filtering AC power applied to a power supply within a computer in said enclosure.
